(19) United States
(12) Patent Application Publication
(10) Pub. No.: US 2012/0094494 A1
(43) Pub. Date: Apr. 19, 2012

(54) METHODS FOR ETCHING MULTI-LAYER HARDMASKS

(75) Inventors: Yu-Chung Chen, Taipei (TW); Shih-Ping Hong, Taichung (TW); Ming-Tsung Wu, Hualien County (TW)

(73) Assignee: MACRONIX INTERNATIONAL CO., LTD., Hsinchu (TW)

(21) Appl. No.: 12/904,892

(22) Filed: Oct. 14, 2010

(51) Int. Cl. H01L 21/308; H01L 21/3065

(52) U.S. Cl. 438/696; 438/711; 257/E21.231; 257/E21.218

(57) ABSTRACT

A method to further adjust the final CD of a material to be etched during an etching process, and after a photolithographic patterning process can include patterning a semiconductor substrate using a mask layer. The mask layer can comprise a hardmask material having a protruding feature with an initial width. A first plasma comprising carbon and fluorine can be introduced into a chamber, where residual carbon and fluorine is deposited on at least the chamber wall. A portion of the mask layer can then be removed with a second plasma incorporating the residual carbon and fluorine, whereby remaining hardmask material forms a feature pattern where the protruding feature has a final width different from the initial width. The feature pattern can then be transferred to the semiconductor substrate using the final width of the at least one protruding feature provided by the remaining hardmask material.

### BACKGROUND

1. Technical Field

The present disclosure relates in general to etching processes used during semiconductor substrate processing, and more particularly to novel etching techniques for fine-tuning patterned critical dimensions during such etching processes.

2. Related Art

The critical dimensions (CD's) and geometries of semiconductor devices and features have decreased dramatically in size since they were first introduced several decades ago.

An important part of the manufacturing process of such semiconductor devices includes the precise formation of a patterned thin film for devices formed on a base substrate. In conventional technologies, such patterned thin films may be formed using chemical reaction of gases on a semiconductor wafer. When patterning thin films, it is desirable that fluctuations in width and other critical dimensions be minimized. Errors in these critical dimensions can result in variations in device characteristics or open-/short-circuited devices, thereby adversely affecting device yield. Thus, as feature sizes decrease, structures must be fabricated with greater accuracy, and therefore manufacturers typically require very little variation in the dimensional accuracy of patterning operations.

However, a key drawback of conventional approaches is that the final CD of the material to be etched (e.g., a polysilicon gate or a metal line) is purely limited by the CD of the overlaying mask layer after the photolithography process is conducted. In view of this significant disadvantage, it would be desirable to have a technique for adjusting the final CDs of the underlying material being etched during the actual etching process following the photolithographic pattern process. This disclosed principles provide such an advantage not available with conventional approaches.

### SUMMARY

The disclosed principles provide a way to further adjust the final CD of a material to be etched during the etching process, and after the photolithographic patterning process. This is accomplished by incorporating residual carbon and fluorine particles that have been deposited on the etching chamber wall, and thus used in later etching process. Accordingly, by incorporating the disclosed principles, the final CD of the material to be etched is not limited by the CD of the overlaying mask layer after the photolithography process is conducted.

In one embodiment, a method of patterning a semiconductor substrate using a mask layer is provided. In such embodiments, the mask layer comprises a hardmask material having at least one protruding feature with an initial width. Such an exemplary method may comprise introducing a first plasma comprising carbon and fluorine into a chamber, wherein residual carbon and fluorine is deposited on at least the chamber wall. The method could then include removing a portion of the mask layer with a second plasma incorporating the residual carbon and fluorine, whereby remaining hardmask material forms a feature pattern where the at least one protruding feature has a final width different from the initial width. Such a method could then include transferring the feature pattern to the semiconductor substrate using the final width of the at least one protruding feature provided by the remaining hardmask material.

In one embodiment, the second plasma comprising argon and oxygen, to create the final width is less than the initial width.

In some embodiments, the method further comprising cleaning the chamber with a plasma gas comprising oxygen prior to transferring the feature pattern to the semiconductor substrate to remove substantially all residual C-F particles in the chamber, to create the final width is greater than the initial width.

In other embodiments of a method of patterning a semiconductor substrate using a mask layer, the mask layer may again comprise a hardmask material having at least one protruding feature with an initial width. In such embodiments, the method may comprise introducing a first plasma comprising carbon and fluorine into a chamber, wherein residual carbon and fluorine is deposited on at least the chamber wall and accumulates on sidewalls of the at least one protruding feature. Such a method could then include etching the mask layer with a second plasma incorporating the residual carbon and fluorine, the etching leaving remaining hardmask material forming a feature pattern where the at least one protruding feature has a final width different from the initial width. Then in such methods, the process could include etching the semiconductor substrate using the mask layer and remaining hardmask material as a mask to transfer the feature pattern to the semiconductor substrate.

In yet other embodiments, methods of patterning a semiconductor substrate using a mask layer, where again the mask layer comprises a hardmask material and has at least one protruding feature with an initial width, may comprise using an etching tool with a first etching plasma comprising carbon and fluorine to form a masking feature in the mask layer having a first line width. In such embodiments, the method could then include using the etching tool with a second etching plasma to adjust the masking feature in the mask layer to a second line width different than the first line width, and to form the masking feature having the second line width in the hardmask material. Then in such embodiments, the method could include transferring the masking feature to the semiconductor substrate using the second line width of the masking feature formed in the hardmask material as a mask.

### BRIEF DESCRIPTION OF THE DRAWINGS

Features, aspects, and embodiments of the inventions are described in conjunction with the attached drawings, in which:

FIG. 1 illustrates an etching process flowchart according to the embodiments of the present application;

FIGS. 2A-2E illustrate cross-sectional views of an exemplary process of one embodiment of manufacturing a patterned mask in accordance with the disclosed principles; and

FIGS. 3A-3D illustrate cross-sectional views of an exemplary process of another embodiment of manufacturing a patterned mask in accordance with the disclosed principles;

FIGS. 4A-4E illustrate cross-sectional views of an exemplary process of yet another embodiment of manufacturing a patterned mask in accordance with the disclosed principles;

FIGS. 4F and 4G illustrate the experimental results according to the exemplary process of FIGS. 4A-4E;

FIGS. 5A-5E illustrate cross-sectional views of an exemplary process of a further embodiment of manufacturing a patterned mask in accordance with the disclosed principles; and

FIGS. 5F-5I illustrate the experimental results according to the exemplary process of FIGS. 5A-5E.

### DETAILED DESCRIPTION

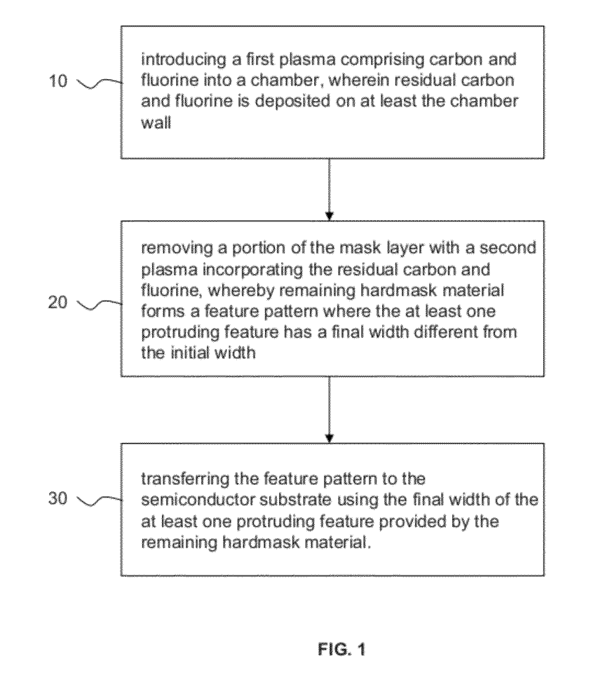

Referring now to FIG. 1, this figure shows an etching process flowchart according to embodiments of the present disclosure. The patterning of a semiconductor substrate includes using a mask layer comprising a photoresist layer, a bottom anti-reflection coating (BARC) layer, and a hardmask material, such as a dielectric anti-reflection coating (DARC) layer, where the mask layer has at least one protruding feature with an initial width D1 after developing. As shown at box 10, the process includes introducing a first plasma comprising carbon and fluorine into a chamber, wherein residual carbon and fluorine is deposited on at least the chamber wall to create the ideal chamber environment for the later etching step. As shown at box 20, the process also includes removing a portion of the mask layer with a second plasma incorporating the residual carbon and fluorine, whereby remaining hardmask material forms a feature pattern where the at least one protruding feature has a final width D2 different from the initial width D1. Finally, as shown at box 30, the process includes transferring the feature pattern to the semiconductor substrate using the final width of the at least one protruding feature provided by the remaining hardmask material.

If one wishes to obtain the final width D2 of the layer to be patterned where the final width D2 is smaller than the initial width D1, then, the second plasma comprising argon and oxygen is used as illustrated at box 20. Otherwise, the second plasma can be such that it does not comprise argon and oxygen. Without the argon and oxygen, the second plasma will yield a final width D2 of the layer to be patterned where the final width D2 is greater than the initial width D1.

As discussed in additional detail below, the present disclosure provides for further adjustments of the final critical dimension, or CD, of a material to be etched during the etching process. This can be accomplished by incorporating residual carbon and fluorine particles that have been deposited on the etching chamber wall, and thus used in later etching process. Accordingly, techniques conducted in accordance with the present disclosure may be performed in a plasma etching chamber or similar equipment capable of performing reactive ion etching (RIE) or other plasma etching processes on semiconductor wafers. Performing plasma etching in such a chamber can include placing a semiconductor wafer in an etching chamber. During the etching process, process gases are introduced into the etching chamber, and are distributed over the areas of the substrate to be etched. Of course, the type of gas(es) selected can be determined based on the material of the layer(s) to be etched. The substrate is typically placed on a cathode, and then the process gas(es) is introduced into the etching chamber, and a plasma is generated from the process gas to selectively etch layers of the substrate. Spent process gases are then evacuated from the chamber via exhaust outlets in the chamber.

Also, the present disclosure provides for further adjustments to the final critical dimension, or CD, of a material to be etched during a second plasma step. If the second plasma comprises Ar and O₂, residual carbon and fluorine particles remaining in the chamber are incorporated in the etching process for trimming the final CD to a narrower width than the initial width after development of the photo resist. On the other hand, if the second plasma etching does not comprise argon and oxygen, the etching process can be used to taper the mask profile in order to achieve the final CD with a wider width than the initial width. Therefore, the present disclosure provides for advantages not available with conventional approaches.

### Embodiment 1

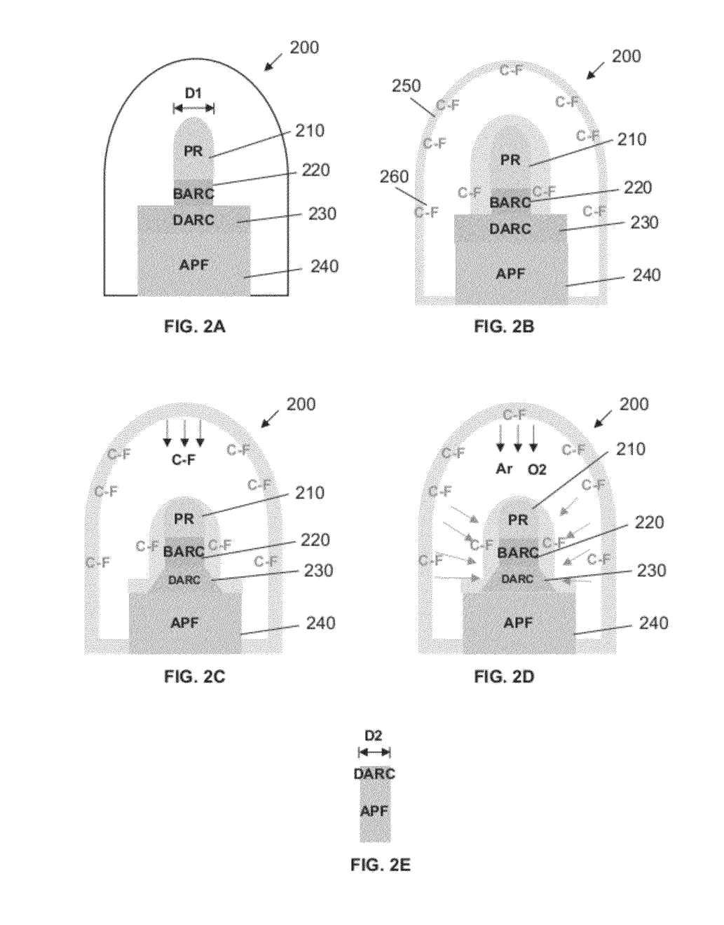

FIG. 2A illustrates a cross-sectional view of a substrate with a multi-layer mask 200 formed thereon. More specifically, an advanced patterning film (APF) layer 240 is formed on a base substrate, a DARC layer 230 on the APF layer 240, a BARC layer 220 over the DARC layer 230, and a photoresist layer 210 on top of the BARC layer 220. In exemplary embodiments, the APF layer 240 is typically about 3000 Å thick, while the DARC layer 230 is typically about 500 Å thick, the BARC layer 220 is about 600 Å thick and the photoresist layer 210 is about 3000 Å thick. Of course, other layer dimensions may be used as well. Moreover, although APF is discussed herein, it should be noted that other layers such as polysilicon may also be employed with the principles disclosed herein to obtained the desired line width.

The etching of features into the organic layer 240, which is done to create the finished mask 200 for patterning underlying device layers, should satisfy several different criteria as discussed above. It should produce a vertical profile in the APF layer 240 to maintain the CD established by the photoresist patterning. For example, for 100 nm features, the variation of the CD at the bottom of the opened APF layer 240 is preferably less than 10 nm from the top. However, when trimming the photoresist and BARC layers 210, 220 using conventional trimming gases such as Cl₂/O₂ or HBr/O₂, too much of the photoresist layer 210 may be removed by the trimming process. As a result, when the DARC layer 230 etching and the APF layer 240 etching are conducted, the excess loss of trimmed photoresist layer 210 results in significant CD variation from top to bottom of the final patterned mask 200.

However, by employing the disclosed principles, tuning the CD of the photoresist layer and BARC layer does not result in excess photoresist loss as is the case with conventional trimming processes. Additionally, tuning such CDs according to the disclosed principles, by employing existing by-products of a prior etching process or a plasma deposition process, less process manufacturing processing steps are required, thus decreasing process time and expense. Specifically, as illustrated in FIG. 2A, the photoresist layer 210 and BARC layer 220 may be initially patterned and etched similar to the conventional process for forming a multi-layer mask 200. If needed, the width of the photoresist and BARC layers 210, 220 may be tuned to a desired CD, which is where the disclosed techniques may be employed. As shown in FIG. 2A, the photoresist layer 210 and BARC layer 220 have one protruding feature with an initial width D1 after pattering and developing of the photolithography process.

Thus, looking at FIG. 2B, a prior semiconductor process, for example, an etching process or a plasma deposition process, was previously conducted that resulted in carbon (C) and fluorine (F) residue remaining on the interior of the processing chamber. More specifically, the prior semiconductor process would include the flowing of one or more processing gases containing carbon and fluorine (C-F) molecules, such as a plasma etching process. After such an etching process is complete, residual C-F molecules would remain on the interior surface of the etching chamber, as illustrated.

In a specific exemplary embodiment, this etching process may include flowing CH₂F₂ during the etching plasma process, and would result in C-F residue remaining inside the etching chamber. Of course, other C-F based etching processes may also be employed. To this end, it is believed that employing an etching gas comprising CH₂F₂ is better than the typical use of CHF₃ (trifluoromethane) or CF₄ (tetrafluoromethane). By way of example, and not limitation of the disclosed principles, an example of performing a process on a semiconductor wafer may comprise, for example, combining CH₂F₂ and CF₄ with high pressure, high source power, and low bias power to achieve this chamber environment tuning purpose. Moreover, lower ESC temperature in the etching tool is also helpful. In this case, for example, 30 mT pressure/400 Watt (source power)/35 Watt (bias power) with 50CF₄/85CH₂F₂/250He, C/E ESC=50/50C.

As illustrated in FIG. 2B, after performing the process (or other similar C-F based process), C-F by-product residue 260 remains on the interior surface of the etching chamber 250 as well as build up on the sidewalls of the PR layer 210 and the BARC layer 220, thus increasing their overall width of the stack layer of the PR layer 210 and the BARC layer 220 despite their slight etching during the process.

Next, as shown in FIG. 2C, the DARC layer 230 may be etched. However in this embodiment, the DARC layer 230 etching process not only incorporates the C-F residue from the previous process, which as before has accumulated on the chamber 250 walls and on the sidewalls of the PR and BARC layers 210, 220, but also includes a C-F based etching plasma for etching the DARC layer 230. Thus, one may further tune the CD of the DARC layer 230 by incorporating the C-F residual particles into the DARC etching process, but by also employing a C-F based etching process for the DARC layer 230, polymer is built up on the sidewalls of the DARC layer 230 during its etching. As illustrated in FIG. 2C, this results in the DARC layer 230 have a tapered profile.

Next, as shown in FIG. 2D, the APF layer 240 can be etched by introducing a second plasma that comprises Ar and O₂ and by incorporating residual carbon and fluorine particles in the chamber. This etching process will trim the final CD to a narrower width D2 than the initial width D1 after the photo resist is developed.

Accordingly, this embodiment of the disclosed principles eliminates the cleaning or otherwise removal of the C-F residue from the chamber 250, which can increase processing time by including such additional cleaning steps. Additionally, since the CD trimming, if desired, is accomplished by employing the C-F residue into a non-C-F based DARC etching process, a separate trimming step (such as the use of Cl₂/O₂, HBr/O₂ or other trimming gases employed in conventional approaches) is not needed, which not only decreases processing time, but reduces processing costs by eliminating such a process. Also, when this exemplary etching and trimming technique was employed by the present inventors, a specific interim CD bias was measured using a scanning electron microscope (SEM). However, after performing the etching process described above that incorporated the residual C-F particles to trim the intermediate mask structure, additional scans from the SEM revealed that the final CD bias had increased from the interim CD bias. Consequently, it was determined that the process described with respect to FIGS. 2A-2E interacts with the photoresist and BARC layers 210, 220 to shrink the final CD of the patterned features of the mask 200 after etching. In this embodiment, once the intermediate structure has been tuned as needed, as illustrated in FIG. 2C, a typical argon and oxygen gas etching process may be conducted to etch the APF layer 240. However, it has been found that by incorporating the residual C-F particles left in the chamber 250 with the argon and oxygen plasma, the APF layer 240 will be etched to the trimmed (smaller) CD achieved with the above-described process. Finally, referring now to FIG. 2E, the feature pattern has been transferred to the semiconductor substrate using the final width D2 of the at least one protruding feature provided by the remaining hardmask material. Specifically, the resulting APF layer 240 has been etched to a trimmed CD D2, where D2<D1, by using remaining DARC layer 230 as a mask as illustrated in FIG. 2E. Accordingly, the finished APF layer 240 obtained the achieved trimmed CD, as desired.

### Embodiment 2

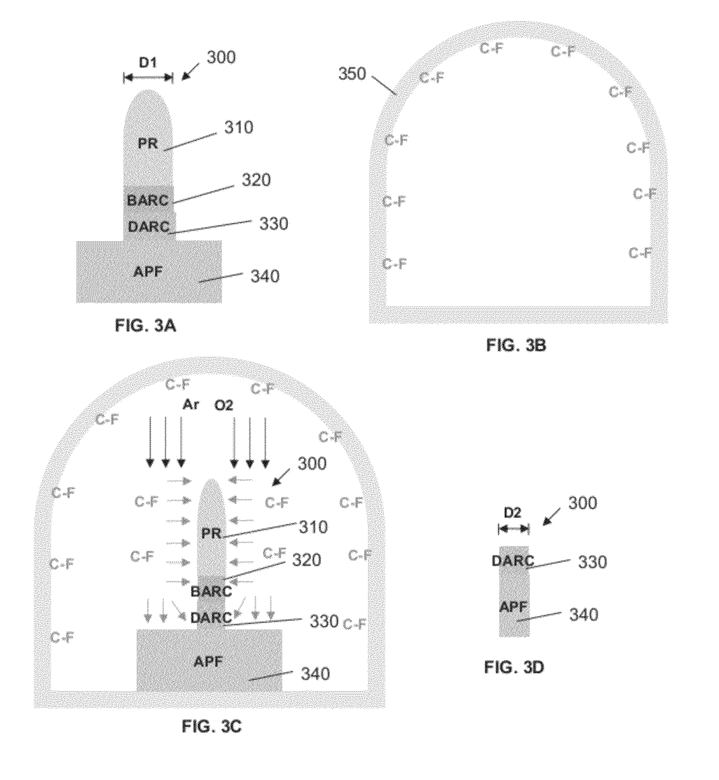

In a related embodiment of the disclosed principles, which is illustrated in FIGS. 3A-3D, the residual C-F molecules from an earlier process, or other similar process incorporating carbon and fluorine, are again incorporated into an etching process associated with an organic-based multi-layer mask 300. More specifically, as illustrated in FIG. 3A, the PR layer 310, BARC layer 320 and the DARC layer 330 are all etched in prior processing steps to create one protruding feature with an initial width D1. After these layers 310, 320, 330 have been etched, the process, or a similar process again incorporating carbon and fluorine, maybe performed in the chamber wall 350, as illustrated in FIG. 3B. For example, such a C-F based process may be employed to etch certain other layers of the devices being formed on the wafer. At some point after the C-F based process, C-F residual particles are again left on the interior surface of the chamber 350 to achieve the desired chamber environment for tuning purposes as disclosed herein.

Turning to FIG. 3C, in accordance with the disclosed principles, the C-F particles left as residue in the chamber 350 and on the sidewalls of the PR, BARC and DARC layers 310, 320, 330 are again employed by the disclosed principles, in situ. More specifically, as illustrated in FIG. 3C, the etching process for etching the APF layer 340 actually incorporates the C-F residual particles in the chamber 350. In such an exemplary process, a typical argon and oxygen gas etching process is conducted to etch the APF layer 340. However, at the same time, the residual C-F particles left in the chamber 350 by keeping the process in situ combine with APF layer 340 etching process to provide a trimming or shrinking of the previously etched photoresist layer 310, BARC layer 320 and DARC layer 330. Therefore, as illustrated in FIG. 3C, as the APF layer 340 is being etched, e.g., with argon and oxygen, and with using the photoresist layer 310, the BARC layer 320 and the DARC layer 330 as an etching mask, the residual C-F particles helps trim this stack of layers during the APF layer 340 etching process, which in turn results in the APF layer 340 being etched to the shrunken CD D2 of this stack mask layers, where D2<D1, as illustrated in FIG. 3D.

Accordingly, with this embodiment of the disclosed principles, the CD of the final patterned mask 300 shown in FIG. 3D has been tuned or biased during the etching of the organic mask layer 340. Advantageously, such an approach again eliminates the need for using conventional trimming gases (e.g., Cl₂/O₂, HBr/O₂), which saves processing expense and time-consuming steps, and thus wafer processing cost and efficiency are improved. Also, a chamber cleaning process, such as O₂ flush, is not required in order to evacuate the residual C-F particles, which therefore further eliminates a step typically used in conventional processes, thereby further improving overall processing cost and efficiency with the disclosed principles.

### Embodiment 3

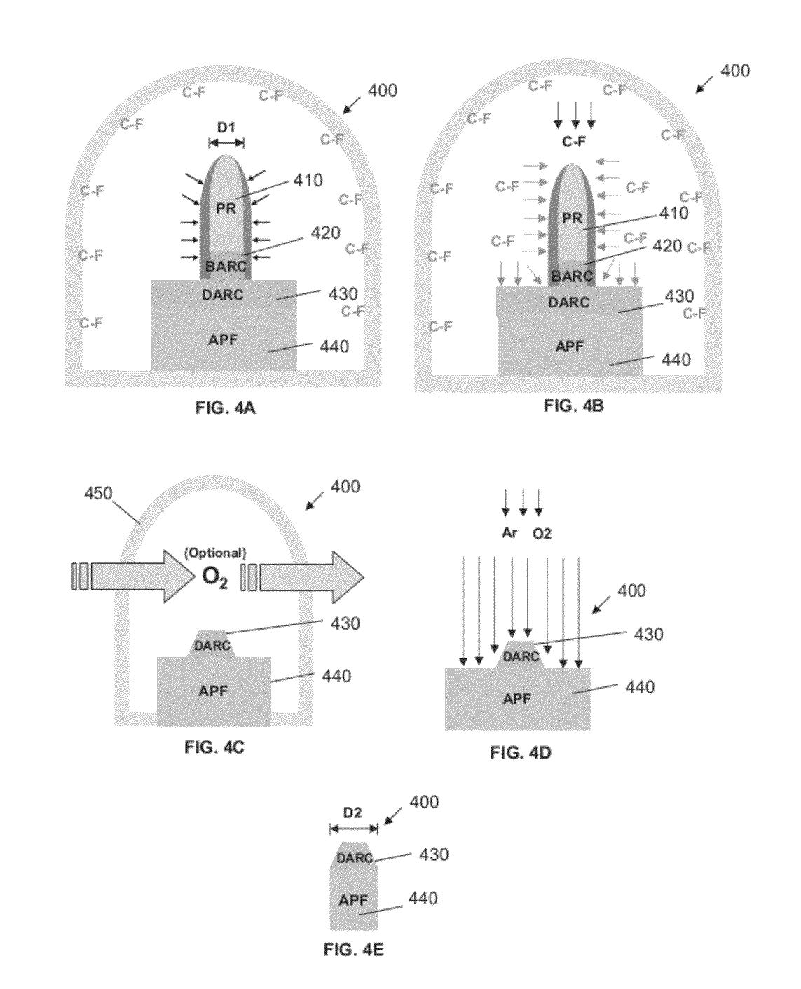

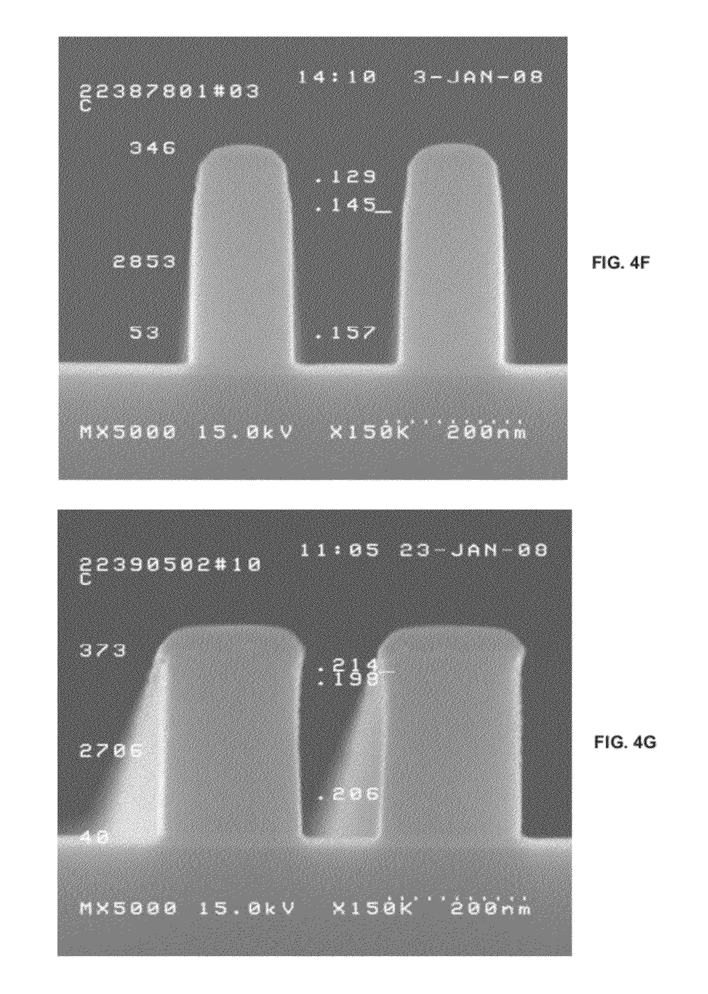

Turning now to FIGS. 4A-4E, illustrated is an alternative embodiment of etching an organic mask 400 similar to the embodiment discussed with reference to FIGS. 2A-2E. As in other embodiment discussed above, the PR and BARC layers 410, 420 may first be etched to a desired dimension. Then, at some point during the processing steps, a plasma deposition process or other similar process incorporating carbon and fluorine is conducted on the wafer. Next, as shown in FIG. 4B, the DARC layer 430 may be etched. However in this embodiment, the DARC layer 330 etching process this time not only incorporates the C-F residue from the plasma deposition process, which as before has accumulated on the chamber 450 walls and on the sidewalls of the PR and BARC layers 410, 420, but also includes a C-F based (shown as black arrows) etching process for etching the DARC layer 430. Thus, as before, tuning the CD of the DARC layer 430 may be accomplished by incorporating the C-F residual particles into the DARC etching process, but by also employing a C-F based etching process for the DARC layer 430, polymer is built up on the sidewalls of the DARC layer 430 during its etching. As illustrated in FIG. 4C, this results in the DARC layer 430 have a tapered profile. After creating the tapered DARC layer 430 profile, a plasma cleaning step is performed to remove the C-F residual particles from the chamber wall as well as from the substrate.

Moving on to FIG. 4D, the tapered profile of the etched DARC layer 430 is then used as an etching mask to etch the underlying APF layer 440 by using Ar and O₂ plasma (arrows in the figure). However, this embodiment of the disclosed principles differs from the above-described embodiments because the polymer built up on the sidewalls of the etched DARC layer 430 provides for a larger CD width of the etched APF layer 440, thereby allowing even further tuning of the final CD for the mask 400. Specifically, the tapered profile of the etched DARC layer 430 is used as an etching mask to etch the underlying APF layer 440, which results in the APF layer 440 being etched with the enlarged CD D2, where D2>D1, as illustrated in FIG. 4D. Accordingly, the finished APF layer 440 obtains the achieved enlarged CD, as desired.

Looking back at FIG. 4C, in one embodiment, the plasma cleaning can be a flush of the chamber 450 with oxygen. In an exemplary embodiment, the oxygen flush may be performed in situ for about 385 sccm of gas for about 70 seconds while the wafer being processed remains in the chamber 450. As a result, residual C-F particles are not only removed from the interior of the chamber, but are also removed from the surface of the wafer, and sidewalls of the features on the wafer, being processed. By performing the oxygen flush after the DARC layer 430 etching and before the APF layer 440 etching, and thereby removing residual C-F particles from the APF layer 440 etching process, additional consuming of the etched DARC layer 430 during the APF layer 440 etching process is prevented. Specifically, in some cases residual C-F particles, such as discussed above with reference to FIGS. 3A-3D, can continue to consume the DARC layer 430 during the APF layer 440 etch since these processes are performed in situ. As described above, it is the gases selected for the APF layer 440 etching process that can react with the C-F particles to further trim the CD during the APF layer 440 etch. Since the etching DARC layer 430 is used as a mask for etching the APF layer 440, additional DARC layer 430 consumption can alter the CD of the DARC layer 430 mask, and thereby alter the CD of the etching APF layer 440. However in this embodiment, in order to prevent additional DARC layer 430 consumption, the oxygen flush is used to remove residual C-F particles. As a result, the CD of the mask is further fine-tunable since not only can trimming of the DARC layer 430 be provided by etching the APF layer 440 with the residual C-F particles remaining in the chamber 450, but the CD can also be left wider than found with conventional approaches since any residual C-F particles are removed from the chamber 450 with the oxygen flush when the APF layer 440 is etched. This is because, as discussed above, the earlier plasma deposition C-F based process left residual C-F particles on the sidewalls of the PR and BARC layers 410, 420, which in turn results in the DARC layer 430 being etched with those residual C-F particles as described in prior embodiments. However in this embodiment, rather than further CD trimming by incorporating residual C-F particles into the APF layer 440 etching process, the C-F is removed from the chamber 450 thereby allowing the selection of a wider CD for the APF layer 440 etch than if C-F remained during the APF layer 440 etching process. Furthermore, again as shown in FIG. 4D, the tapered profile of the etching DARC layer 430 is then used as a mask to etch the underlying APF layer 440, and because the polymer built up on the sidewalls of the etched DARC layer 430 provides for a larger CD width, even further tuning of the final CD for the mask 400 is provided.

In experiments performed by the present inventors, CD bias measured from top to the bottom of the final mask 400 formed by the etched APF layer 440 measured about −19.5 nm. A reproduction of the SEM scan of this experimental result is illustrated in FIG. 4F. However, when the oxygen flush was performed prior to the APF layer 440 etching process in accordance with this embodiment of the disclosed principles, CD bias measured a change of +45 nm. A reproduction of the SEM scan of this experimental result is illustrated in FIG. 4G.

### Embodiment 4

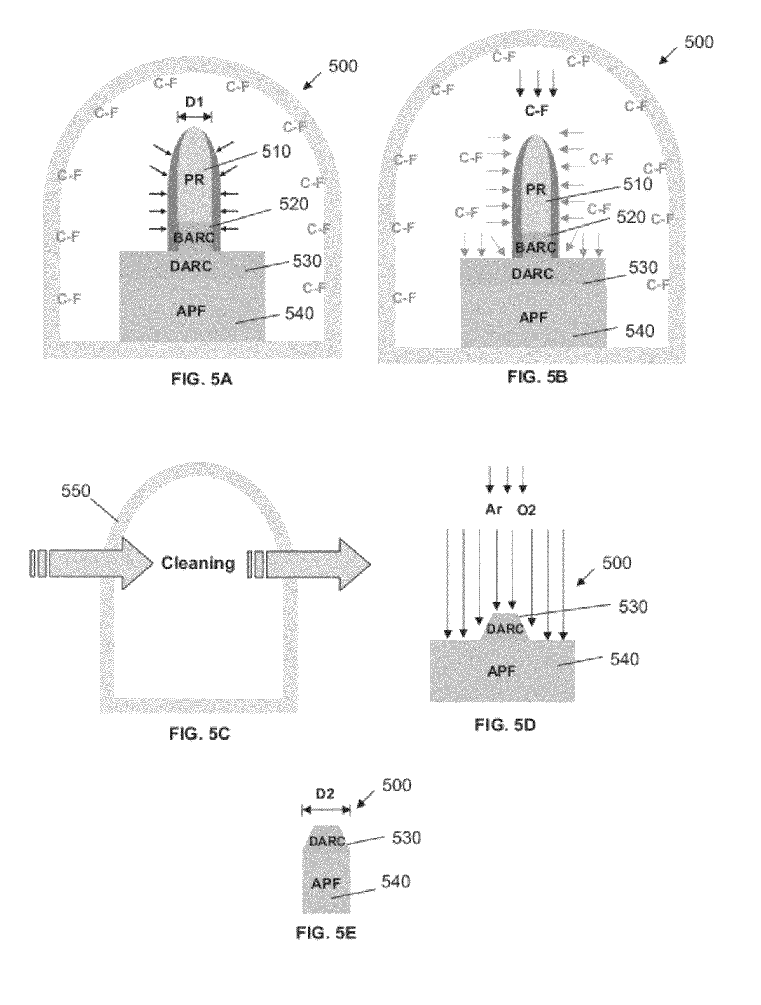

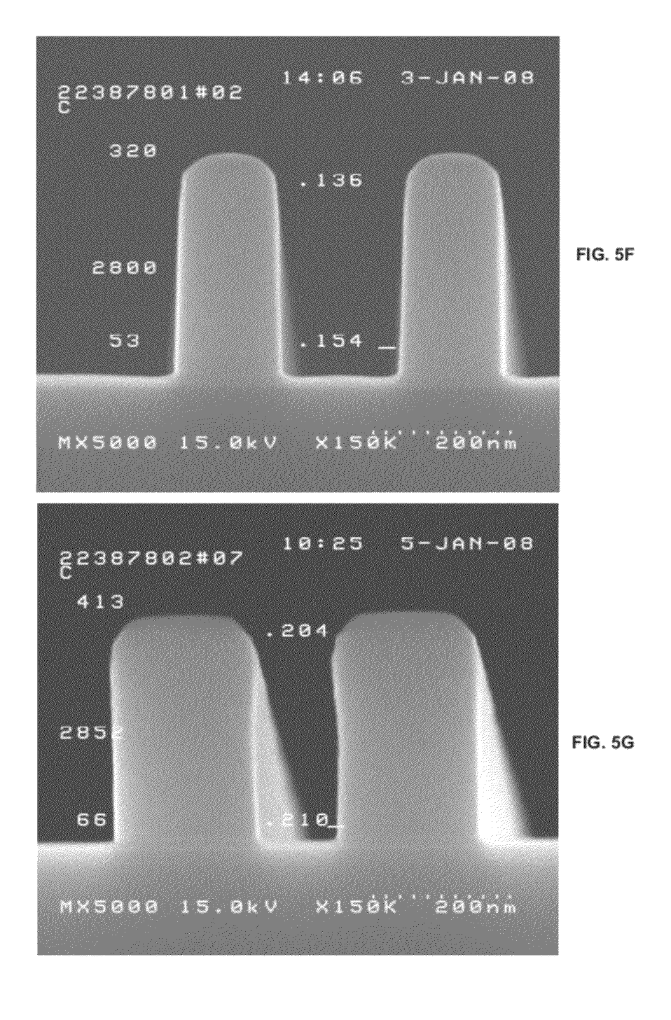

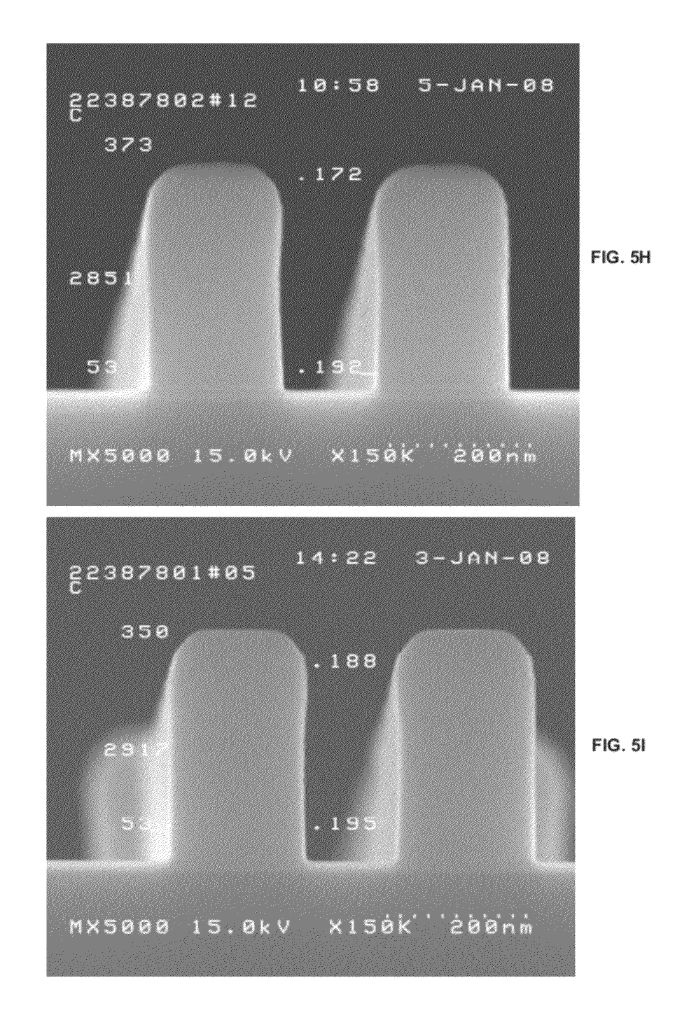

In other embodiments of the disclosed principles, with reference to FIGS. 5A-5D, another plasma cleaning process may be used on the chamber during the processing of the final patterned mask. The process of FIGS. 5A-5D is similar to the process of FIGS. 4A-4D, with the primary difference being shown in FIG. 5C. Specifically, looking at FIG. 5A, the PR and BARC layers 510, 520 may first be etched to a desired dimension. Then, again at some point during the processing steps, a plasma deposition process or other similar process incorporating carbon and fluorine is conducted on the wafer. Next, as shown in FIG. 5B, the DARC layer 530 may be etched. As before, the DARC layer 530 etching process again incorporates the C-F residue from the plasma deposition process and from the sidewalls of the PR and BARC layers 510, 520. Thus, as before, tuning the CD of the DARC layer 530 may be accomplished by incorporating the C-F residual particles into the DARC etching process. As with the embodiments discussed with reference to FIGS. 4A-4E, the DARC layer 530 etching process may again include a C-F based etching process. Thus, as before, tuning the CD of the DARC layer 530 may be accomplished by incorporating the C-F residual particles into the DARC etching process. But by also employing a C-F based etching process for the DARC layer 430, polymer is again built up on the sidewalls of the DARC layer 530 during its etching, as illustrated in FIG. 5D, again resulting in the DARC layer 530 having a tapered profile.

Looking back at FIG. 5C, in this embodiment of the disclosed etching techniques, the APF layer 540 is once again not immediately etched. Instead, in this alternative embodiment, a plasma cleaning process (rather than an oxygen flush) is used to clean the chamber 550 in an ex situ process. In one embodiment, the chamber cleaning process is using hydrogen oxide plasma, or alternatively, using fluoride compound such as SF₆. As a result of the plasma cleaning process, residual C-F particles are removed from the interior of the chamber 550. Moreover, the cleaning process, may also be used to strip some or all of the PR and/or BARC layers 510, 520, but additional process steps for such stripping may also be employed. By performing the cleaning process after the DARC layer 530 etching and before the APF layer 540 etching, and thereby removing residual C-F particles from the APF layer 540 etching process, additional consuming of the etched DARC layer 530 during the APF layer 540 etching process is prevented.

Thereafter, the wafer may be placed back in the chamber 550, and the APF layer 540 may be etched as shown in FIG. 5D. Thus, similar to embodiments employing an oxygen flush, the CD of the mask is further fine-tunable since not only can trimming of the DARC layer 530 be provided by etching it with the residual C-F particles remaining in the chamber 550, but then that tuned CD width can be prevented from any further trimming when the APF layer 540 is etched by performing the plasma cleaning process. After the APF layer 540 is etched, the resulting APF layer 540 has the enlarged CD D2, where D2>D1, as illustrated in FIG. 5E. Accordingly, the finished APF layer 540 obtained the achieved enlarged CD, as desired.

In practice, the etching process described with respect to FIGS. 5A-5E may also result in a mask feature pattern exhibiting a difference of about −20 nm when measured from top to bottom. A reproduction of an SEM scan of a −20.5 nm CD bias is illustrated in FIG. 5F. In sum, while CD biases of −20 nm are an improvement over conventional mask etching techniques, positive differential CD biases may be even more beneficial. Certain embodiments of the mask etching technique disclosed herein may achieve such positive CD biases, as discussed in detail below, by converting the process to an ex situ process. Specifically, a plasma cleaning process is interposed after conducting a plasma deposition process on the wafer for processing other layers of the wafer. However, the plasma cleaning process may intervene at various points in the overall mask etching process, depending on the embodiment of the disclosed principles. A reproduction of an SEM scan from an experimental result of such an embodiment is illustrated in FIG. 5G, which illustrates a CD bias of +44.2 nm.

In alternative embodiments of the embodiments incorporating a plasma cleaning process during the overall mask etching process, the plasma cleaning process on the chamber 550 may be interposed still after the plasma deposition process is used to process certain layers of the wafer, and after etching of the photoresist and BARC layers 510, 520, but prior to the DARC layer 530 etching process illustrated in FIG. 5B. The APF layer 540 etch may then be performed immediately following the DARC layer 530 etch. A reproduction of an SEM scan from an experimental result of such an embodiment is illustrated in FIG. 5H, which illustrates a CD bias of +23.4 nm.

In other alternative embodiments of the embodiments incorporating a plasma cleaning process, multiple plasma cleaning processes on the chamber 550 may be employed. For example, a first plasma cleaning process may be interposed after the plasma deposition process used on a wafer and after etching of the photoresist and BARC layers 510, 520 stack, and prior to the DARC layer 530 etching process illustrated in FIG. 5B. Then the DARC layer 530 etch may be performed. Additionally, however, a second plasma cleaning process may be interposed directly after the DARC layer 530 etch, and prior to the etching of the APF layer 540. The APF layer 540 etch may then be performed immediately following the second plasma cleaning process as shown in FIG. 5D. A reproduction of an SEM scan from an experimental result of such an embodiment is illustrated in FIG. 51, which illustrates a CD bias of −28.5 nm.

While various embodiments in accordance with the disclosed principles have been described above, it should be understood that they have been presented by way of example only, and are not limiting. Additionally, although the disclosed principles are described in terms of exemplary embodiments, it should be understood that one or more principles from one embodiment described above may be incorporated into the exemplary etching technique of another process where advantageous, and thus the embodiments disclosed herein should be interpreted as mutually exclusive. Accordingly, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A method of patterning a semiconductor substrate using a mask layer, the mask layer comprising a hardmask material and having at least one protruding feature with an initial width, the method comprising:
introducing a first plasma comprising carbon and fluorine into a chamber, wherein residual carbon and fluorine is deposited on at least the chamber wall;
removing a portion of the mask layer with a second plasma incorporating the residual carbon and fluorine, whereby remaining hardmask material forms a feature pattern where the at least one protruding feature has a final width different from the initial width; and
transferring the feature pattern to the semiconductor substrate using the final width of the at least one protruding feature provided by the remaining hardmask material.

2. A method according to claim 1, wherein the mask layer also comprises a photoresist layer, and a bottom antireflective coating formed under the photoresist layer.

3. A method according to claim 2, wherein the hardmask material comprises a dielectric antireflective coating formed under the bottom antireflective coating.

4. A method according to claim 1, wherein the semiconductor substrate comprises a carbon-based material.

5. A method according to claim 1, wherein introducing a first plasma comprising carbon and fluorine comprises performing an etching process for etching polysilicon performed at a temperature of about 20° C. to 80° C., at a pressure of about 20 torr to 70 torr, and flowing a gas comprising CH₂F₂ and CF₄, for about 10 to 70 seconds.

6. A method according to claim 1, wherein introducing a first plasma comprising carbon and fluorine into a chamber further comprises accumulating carbon and fluorine on sidewalls of the at least one protruding feature.

7. A method according to claim 1, wherein the second plasma comprises argon and oxygen.

8. A method according to claim 7, wherein the final width is less than the initial width.

9. A method according to claim 1, the method further comprising cleaning the chamber with a plasma gas prior to transferring the feature pattern to the semiconductor substrate to remove substantially all residual C-F particles in the chamber.

10. A method according to claim 9, wherein the final width is greater than the initial width.

11. A method according to claim 9, wherein, in the cleaning of the chamber, the plasma gas comprises oxygen.

12. A method of patterning a semiconductor substrate using a mask layer, the mask layer comprising a hardmask material and having at least one protruding feature with an initial width, the method comprising:
introducing a first plasma comprising carbon and fluorine into a chamber, wherein residual carbon and fluorine is deposited on at least the chamber wall and accumulates on sidewalls of the at least one protruding feature;
etching the mask layer with a second plasma incorporating the residual carbon and fluorine, the etching leaving remaining hardmask material forming a feature pattern where the at least one protruding feature has a final width different from the initial width; and
etching the semiconductor substrate using the mask layer and remaining hardmask material as a mask to transfer the feature pattern to the semiconductor substrate.

13. A method according to claim 12, wherein the mask layer comprises a photoresist layer, the hardmask material comprises an antireflective coating, and the semiconductor substrate comprises a carbon-based material.

14. A method according to claim 12, wherein the second plasma comprises argon and oxygen.

15. A method according to claim 14, wherein the final width is less than the initial width.

16. A method according to claim 12, the method further comprising cleaning the chamber with a plasma gas prior to transferring the feature pattern to the semiconductor substrate to remove substantially all residual C-F particles in the chamber.

17. A method according to claim 16, wherein the final width is greater than the initial width.

18. A method of patterning a semiconductor substrate using a mask layer, the mask layer comprising a hardmask material and having at least one protruding feature with an initial width, the method comprising:
using an etching tool with a first etching plasma comprising carbon and fluorine to form a masking feature in the mask layer having a first line width;
using the etching tool with a second etching plasma to adjust the masking feature in the mask layer to a second line width different than the first line width, and to form the masking feature having the second line width in the hardmask material; and
transferring the masking feature to the semiconductor substrate using the second line width of the masking feature formed in the hardmask material as a mask.

19. A method according to claim 18, wherein the second plasma comprises argon and oxygen.

20. A method according to claim 18, the method further comprising cleaning the chamber with a plasma gas comprising oxygen prior to transferring the feature pattern to the semiconductor substrate to remove substantially all residual C-F particles in the chamber.
